(19) United States
(12) Patent Application Publication
(10) Pub. No.: US 2008/0088039 A1
(43) Pub. Date: Apr. 17, 2008

(54) Substrate with heat-dissipating dummy pattern for semiconductor packages

(75) Inventors: Ming-Hsun Lee, Tainan (TW); Pi-Chang Chen, Tainan (TW)

Correspondence Address: TROXELL LAW OFFICE PLLC;SUITE 1404, 5205 LEESBURG PIKE, FALLS CHURCH, VA, 22041, US

(73) Assignee: ChipMOS TECHNOLOGIES INC.

(21) Appl. No.: 11/790,828

(22) Filed: Apr. 27, 2007

(30) Foreign Application Priority Data
Oct. 14, 2006 (CN) 095137881

(51) Int. Cl. H01L 23/48

(52) U.S. Cl. 257/786; 257/E23.01

(57) ABSTRACT

A semiconductor packaging substrate with heat-dissipating dummy patterns primarily comprises a dielectric, a plurality of leads, at least a dummy pattern and a plurality of heat-conducting bars where the leads and the dummy pattern are formed on the dielectric. At least one of the leads is a high-power lead. The dummy pattern is disposed close to the high-power lead. The heat generated by the high-power lead is dissipated through the heat-conducting bars which thermally couple the high-power lead to the dummy pattern. Moreover, the leads, the dummy patterns, and the heat-conducting bars are made of a same metal layer. Therefore, an extra heat-dissipating path is created without affecting the flexibility of the substrate and increasing the cost, the dimension or the thickness of the substrate.

### FIELD OF THE INVENTION

The present invention relates to a substrate for semiconductor packages, especially, to a semiconductor packaging substrate with dummy patterns for heat-dissipation.

### BACKGROUND OF THE INVENTION

In the conventional semiconductor packaging technologies, a heat spreader will be added to one of the exposed surfaces of the semiconductor package such as on the exposed back surface of a bare die or on the top surface of an encapsulant to enhance heat dissipation. However, with an added heat spreader, the appearance, the thickness, and the weight of a semiconductor package will be changed, which is not suitable for Chip-On-Film package, COF, nor Tape-Carrier-Package, TCP.

For example, as shown in FIG. 1, a conventional COF semiconductor package comprises a flexible substrate 100, a chip 10 and a liquid encapsulant 20. The chip 10 has a plurality of bumps 11 bonded to a plurality of leads 120 on the flexible substrate 100. Moreover, the encapsulant 20 fills the gaps between the chip 10 and the substrate 100 by dispensing. The substrate 100 comprises a dielectric layer 110, a plurality of leads 120 and a solder mask 130 where the leads 120 are formed on the dielectric layer 110. As shown in FIG. 2, at least one of the leads 120 is a high-power lead 121 with a concave 122 either blank or filled with reinforced patterns to absorb stresses. As shown in FIG. 1, the solder mask 130 partially covers the leads 120 including the high-power lead 121 with an opening 131 to expose the inner ends of the leads 120 for bonding the bumps 11 of the chip 10. Therefore, the heat generated from the high-power lead 121 can not easily be dissipated because the high-power lead 121 is covered by the solder mask 130; it further causes uneven temperature distributions in the substrate 100 leading to peeling of the leads 120 from the dielectric layer 110 or warpage of the substrate 100.

### SUMMARY OF THE INVENTION

The main purpose of the present invention is to provide a semiconductor packaging substrate with heat-dissipating dummy patterns where the heat generated from the high-power leads can be effectively dissipated via the specially designed heat-dissipating dummy patterns without increasing the dimension or the thickness of the semiconductor packaging substrate.

The second purpose of the present invention is to provide a semiconductor packaging substrate with heat-dissipating dummy patterns thermally coupled to a high-power lead by a plurality of heat-conducting bars to maintain the stress buffering capabilities of the high-power lead.

According to the present invention, a semiconductor packaging substrate with heat-dissipating dummy patterns primarily comprises a dielectric layer, a plurality of leads, at least a dummy pattern and a plurality of heat-conducting bars where the leads are formed on the dielectric and at least one of the leads is a high-power lead. The heat-dissipating dummy pattern is disposed on the dielectric layer and close to the high-power lead. The heat-conducting bars thermally couple the high-power lead to the heat-dissipating dummy pattern. Additionally, the leads, the dummy patterns and the heat-conducting bars are made of the same metal layer.

### DESCRIPTION OF THE DRAWINGS

FIG. 1 shows a cross-sectional view of a conventional COF package.

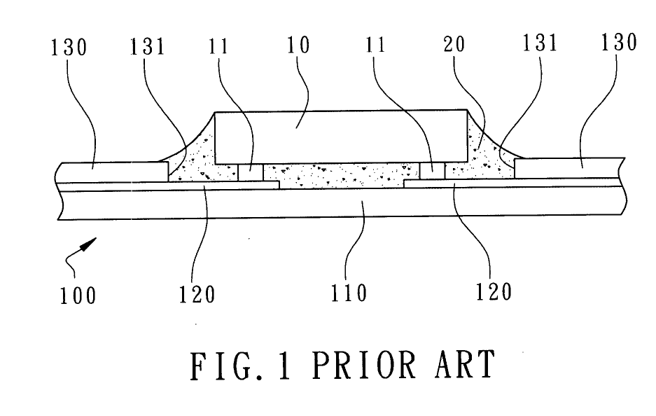

FIG. 2 shows partially a top view of a substrate of the conventional COF package.

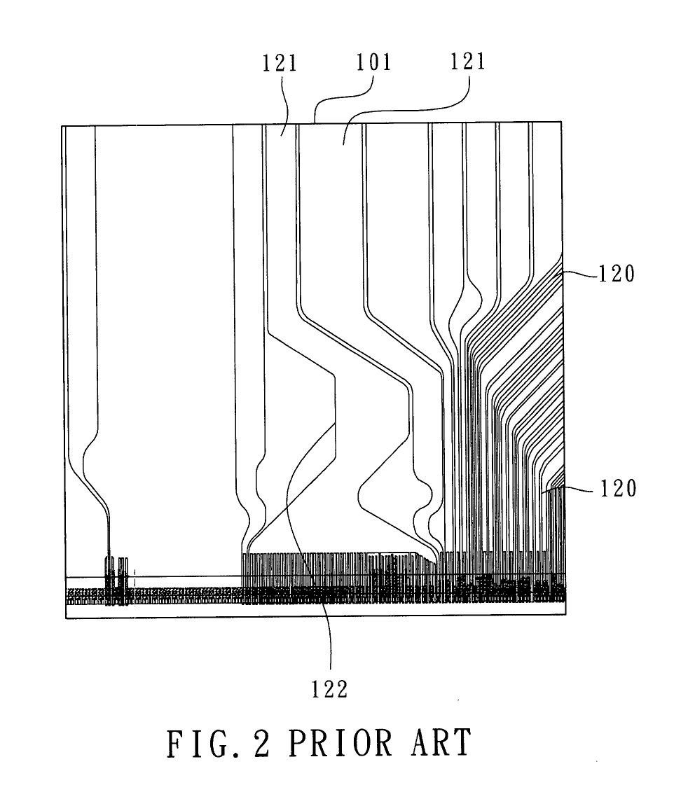

FIG. 3 shows partially a top view of a semiconductor packaging substrate with heat-dissipating dummy patterns according to the preferred embodiment of the present invention.

FIG. 4 shows partially a cross-sectional view of the semiconductor packaging substrate with heat-dissipating dummy patterns according to the preferred embodiment of the present invention.

### DETAIL DESCRIPTION OF THE INVENTION

Please refer to the attached drawings, the present invention will be described by means of embodiment(s) below.

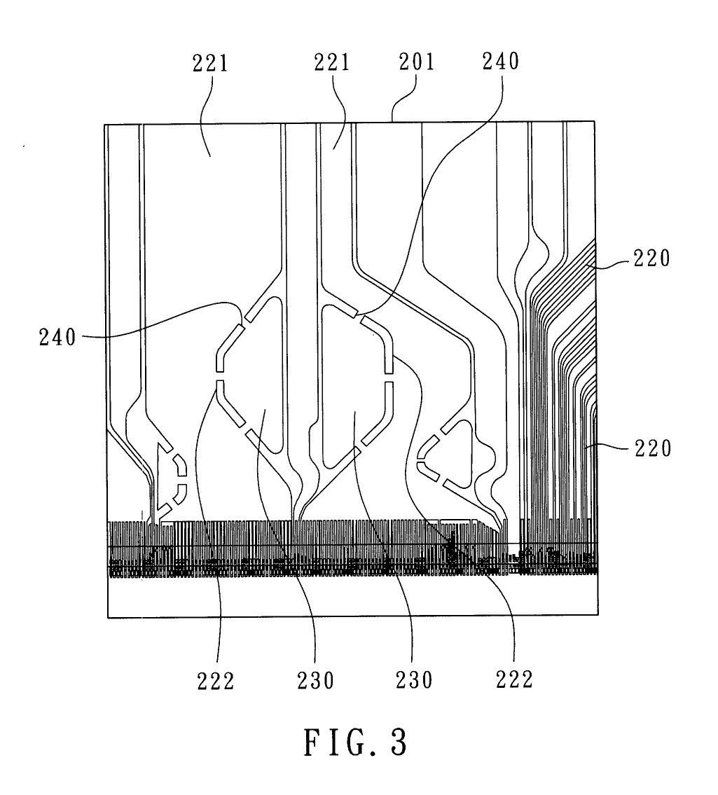

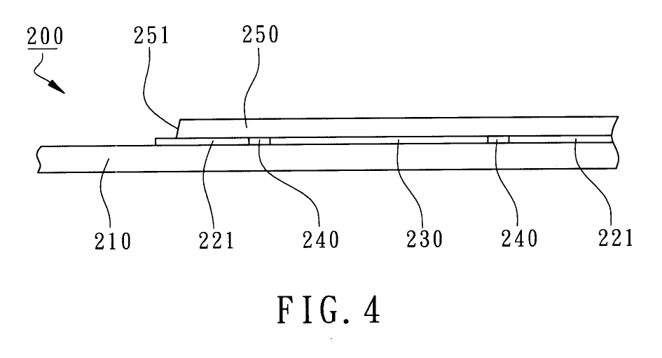

According to the first embodiment of the present invention, as shown in FIG. 3 and FIG. 4, a semiconductor packaging substrate 200 with heat-dissipating dummy patterns includes a dielectric layer 210, a plurality of leads 220, at least a dummy pattern 230 and a plurality of heat-conducting bars 240 where the leads 220 are formed on the dielectric layer 210 and the leads 220 include at least a high-power lead 221. In the present embodiment, the high-power leads 221 may be electrical-power leads or high-frequency leads; moreover, the width of the high-power lead 221 is larger than or equal to that of the other leads 220. In this embodiment, the substrate 200 is a flexible film which can be implemented in COF or TCP, and the dielectric layer 210 is, for example, of polyimide or the like to provide good bending flexibility and good electrical isolation.

As shown in FIG. 3, the dummy pattern 230 is formed on the dielectric layer 210 and close to the high-power lead 221. Preferably, the dummy pattern 230 is disposed at the input side 201 of the substrate 200, which provides a larger area to configure heat-dissipating patterns compared to the output side (not shown) of the substrate 200. The dummy pattern 230 occupies the leadless area of the dielectric layer 210 and supplies no electrical functions.

The heat-conducting bars 240 thermally couple the high-power leads 221 to the dummy pattern 230 so that the dummy pattern 230 is not directly connected to the high-power leads 221. The widths of the heat-conducting bars 240 can be equal to that of the leads 220.

Preferably, the high-power leads 221 has a concave 222 to enhance the flexibility as well as the stress-buffering capability and to avoid broken leads and interface delamination between the high-power lead 221 and the dielectric layer 210. The dummy pattern 230 is accommodated in the concave 222 to dissipate the heat generated from the high-power leads 221 through the heat-conducting bars 240 such that it can enhance heat dissipation of the high-power leads 221 without affecting the stress-buffering capability. In the present embodiment, the widths of the heat-conducting bars 240 cannot be larger than that of the high-power leads 221 so that any impact on the stress-buffering capability can be avoided.

As shown in FIG. 4, the leads 220 including the high-power leads 221, the dummy pattern 230 and the heat-conducting bars 240 are made of the same metal layer to reduce the cost of disposing the dummy pattern 230 and to keep the flexibility of the substrate 200. In the present embodiment, the semiconductor packaging substrate 200 further comprises a solder mask 250 formed over the dielectric layer 210 to partially cover the leads 220 including the high-power leads 221 and the heat-conducting bars 240 to avoid the breaks of the heat-conducting bars 240 and to prevent the electrical shorts among the leads 220, the high-power leads 221, and the heat-conducting bars 240 due to contaminations. In this embodiment, the dummy patterns 230 are fully covered by the solder mask 250. In different embodiment, the dummy patterns 230 may be partially exposed from the solder mask 250. Normally the solder mask 250 has an opening 251 corresponding to the die-attaching area to expose the inner ends of the leads 220 including the high-power leads 221 to bond with a plurality of bumps on a chip, not shown in the figure.

Therefore, when the semiconductor packaging substrate 200 is implemented in a semiconductor package, the heat generated from the high-power leads 221 will be conducted to the dummy patterns 230 through the heat-conducting bars 240. The heat-dissipating efficiency is effectively enhanced by developing another heat dissipating path without increasing the dimension or the thickness of the semiconductor packaging substrate 200.

The above description of embodiments of this invention is intended to be illustrative and not limiting. Other embodiments of this invention will be obvious to those skilled in the art in view of the above disclosure.

What is claimed is:

1. A semiconductor packaging substrate comprising:
a dielectric layer;
a plurality of leads formed on the dielectric layer wherein the leads include at least a high-power lead;
at least a dummy pattern formed on the dielectric layer and disposed close to the high-power lead; and
a plurality of heat-conducting bars thermally coupling the high-power lead to the dummy pattern;
wherein the leads, the dummy patterns and the heat-conducting bars are made of the same metal layer.

2. The semiconductor packaging substrate of claim 1, wherein the high-power lead has a concave for accommodating the dummy pattern.

3. The semiconductor packaging substrate of claim 1, wherein the width of the high-power lead is larger than or equal to that of the other leads.

4. The semiconductor packaging substrate of claim 1, wherein the dummy pattern is disposed at an input side of the substrate.

5. The semiconductor packaging substrate of claim 1, further comprising a solder mask partially covering the leads and the heat-conducting bars.

6. The semiconductor packaging substrate of claim 1, wherein the substrate is a flexible film.

7. The semiconductor packaging substrate of claim 6, wherein the flexible film is implemented in COF (Chip-On-Film) or TCP (Tape Carrier Package).
